(19) United States
(12) Patent Application Publication
(10) Pub. No.: US 2023/0393187 A1
(43) Pub. Date: Dec. 7, 2023

(54) SYSTEM AND METHOD FOR ON-LINE TRANSFORMER BUSHINGS POWER FACTOR MONITORING

(71) Applicant: ZTZ Service International, Inc., North Miami Beach, FL (US)

(72) Inventors: Zalya Berler, Sunny Isles Beach, FL (US); Vladimir Prykhodko, Sunny Isles Beach, FL (US); Daniel Berler, Sunny Isles Beach, FL (US); Vasily Topko, Tamarac, FL (US)

(73) Assignee: ZTZ Service International, Inc., North Miami Beach, FL (US)

(21) Appl. No.: 17/831,456

(22) Filed: Jun. 3, 2022

(51) Int. Cl. G01R 31/12; G01R 31/62

(52) U.S. Cl. CPC G01R 31/1245; G01R 31/62

(57) ABSTRACT

A system (10) or method (700) for on-line monitoring of a transformer (10) can include a first sensor (15a) coupled to a primary high voltage side bushing (14a) for monitoring bushing dielectric losses on a high voltage side of the transformer, a second sensor (17a) coupled to a secondary low voltage side bushing (16a) for monitoring bushing dielectric losses on a low voltage side of the transformer, and one or more processors (18) coupled to the first and second sensors. The one or more processors can simultaneously sample (701) data from the first and second sensor, where the primary high voltage side bushing and the secondary low voltage side bushing are operating on a same phase, compare (704) the sampled data over time to provide sampled readings, and generate (706) an alert upon detection of a deviation over a predetermined threshold between sampled readings for the sampled data over time.

### FIELD OF THE DISCLOSURE

The present disclosure generally relates to systems and methods for monitoring the performance of power transformers. More particularly, the present invention relates to the testing of power transformers while they are still online using a measurement of power factor (also known as the “dielectric loss angle' or “dissipation factor') to enable diagnosis of a faulty power transformer, a faulty bushing, or a faulty corresponding pair of high and low voltage bushings within a transformer.

### BACKGROUND

There are well established techniques for testing deterioration of high Voltage (HV) equipment, and specifically the insulators of that equipment. Such methods involve first disconnecting the equipment from the HV line. The purpose of disconnecting the equipment is to avoid the Substantial danger to personnel and/or testing equipment that is connected to high power equipment. In practice, it has been very expensive to disconnect equipment for testing. In addition to the man-power required to disconnect the HV equipment, connect it to test equipment and perform the test, the service of the equipment is lost for whatever period of time it takes to disconnect, make the test and reconnect. If there are large numbers of transformers and circuit breakers, and other equipment to be tested, the shut-down can be lengthy and the loss of revenue to the power company very substantial.

Other techniques are done on-line without necessarily taking the transformer or other high voltage equipment offline. Each technique has their advantages and disadvantages.

A first technique monitors phase-to-phase bushing power factor (adjacent phase). Such phase-to-phase monitoring can be installed on a standalone transformer and does not require an external reference for comparison. Unfortunately, the technique is exclusive only for one bushing and detecting one defective bushing at the set or installation of such bushings. The phase-to-phase technique is also susceptible to network system disturbances, particularly if the phase-to-phase angle differs from 120 degrees. Further, this technique has high power factor dispersion due to phase-to-phase variation. European Patent Application No. EP3206041A1 by ABB Schweiz AG entitled A SYSTEM AND METHOD FOR MONITORING TRANSFORMER BUSHINGS published on Aug. 16, 2017 and U.S. Pat. No. 6,927,522 by Anand et al. entitled POWER FACTOR POWER FACTOR/TAN d TESTING OF HIGH VOLTAGE BUSHINGS ON POWER TRANSFORMERS, CURRENT TRANSFORMERS, AND CIRCUIT BREAKERS are both examples of the phase-to-phase technique.

In U.S. Pat. No. 6,927,522, power factor is measured to diagnose the condition of high powered Stand-off insulators, which include a roll of insulating material carrying an intermediate layer of conductor between layers of the insulating material around a central high voltage (HV) conductor in a hollow insulator body, is accomplished while the power System is subject to full voltage. A coupling means provides a capacitive Voltage divider with a tap at a low Voltage point on the conductor within the insulator Structure. The divider with the coupling means is also provided with an external low voltage connector and a ground connector. A computer is connected to the external connections of the coupling means and contains Software to convert a received analog signal to digital, and subject the digital signal to a fast Fourier transform analysis to produce an output signal representative of the power factor. The computer is arranged to calculate, process and store the bushing insulator power factor at periodic intervals. The invention in U.S. Pat. No. 6,927,522 also involves a method of measuring power factor in an insulation structure as described and then involving disconnecting high power from the HP equipment. A connection is made from a conductive capacitive layer at the low voltage end of the insulation roll in the bushing to a capacitive voltage divider in a bushing tap coupler to provide an output from the coupler on the order of household voltage when HV is reconnected to the equipment. Low voltage from the coupler to a further voltage divider circuit further reduces the voltage at the output to a level acceptable to a computer. The high power is then reconnected to the equipment So the computer voltage is available on demand at the output of the measuring equipment. The invention also provides a method of testing HV insulators by providing low voltage output across a passage divider from a tap to the conductive capacitive layer at the low voltage end of the conductor within the insulation roll within the bushing. The bushing tap coupler is connected to a voltage reduction circuit to reduce voltage to a level acceptable to a computer.

A second technique power factor measuring method uses an external reference with a voltage transformer or coupling capacitor voltage transformer (VT/CCVT). Such technique provides good accuracy in power factor monitoring and not susceptible to network system disturbances. Also, this technique can detect more than one bushing condition worsening within a set of bushings. Unfortunately, the external reference technique requires additional hardware such as voltage transformers and/or coupling capacitor voltage transformers and requires pulling cables from a free standing voltage transformer and/or coupling capacitor to the location of a control unit for the measuring of the dielectric losses parameters according to this second technique. U.S. Pat. No. 4,757,263 to Cummings, III et al. entitled INSULATION POWER FACTOR ALARM MONITOR published on Jul. 12, 1988 and US Patent Application No. 2016/0252564 by Wu et al. entitled METHOD AND APPARATUS FOR MONITORING CAPACITOR BUSHINGS FOR THREE-PHASE AC SYSTEM are both examples of the technique using the external reference with the voltage transformer or coupling capacitor voltage transformer.

A third approach or technique compares measurements between two separate transformers. Although this comparison approach provides good accuracy in power factor monitoring, is not susceptible to network system disturbances, and can detect more than one bushing condition worsening within a set of bushings, there are a number of detriments. The comparison approach requires additional hardware such as another transformer or current transformer as a reference to be present on the power station. The comparison approach further requires pulling cables from the reference transformer or current transformers to the location of the control unit for the measuring of the dielectric losses parameters according to this third technique. Furthermore, the comparison approach is not sensitive or conducive to determining if a pair of bushings start to degrade at the same rate.

The three techniques described above, namely the phase-to-phase bushing power factor (adjacent phase), the external reference with VT/CCVT, and the comparison techniques all have limited suitability or require extra hardware for determining the health of a transformer bushing or a number of bushings on a power transformer.

### SUMMARY

In some embodiments, a system for on-line monitoring a condition of a transformer can include a first sensor coupled to a primary high voltage side bushing for monitoring power transformer bushing dielectric losses on a primary high voltage side of the transformer, a second sensor coupled to a secondary low voltage side bushing for monitoring power transformer bushing dielectric losses on a secondary low voltage side of the transformer, and one or more processors coupled to the first sensor and the second sensor. The one or more processors are configured to perform the operations of simultaneously sampling data from the first sensor and the second sensor, where the primary high voltage side bushing and the secondary low voltage side bushing are operating on a same phase, comparing the sampled data over time to provide sampled readings on the same phase, and generating an alert upon detection of a deviation over a predetermined threshold between sampled readings for the sampled data over time.

In some embodiments, the first sensor is a test tap coupled to the primary high voltage side bushing and the second sensor is a test tap coupled to the secondary low voltage side bushing. In some embodiments, the first sensor and second sensor compare a phase angle of leakage between the primary high voltage side bushing and the secondary low voltage side bushing. In some embodiments, the transformer is a single phase transformer and in others it is a single three-phase transformer having three primary high voltage side bushings and three secondary low voltage side bushings. In some embodiments, the transformer is a three single-phase transformer having three primary high voltage side bushings and three secondary low voltage side bushings.

In some embodiments in the case of a single phase transformer having three primary high side and three secondary low side bushings, the first sensor is coupled to each of the three respective primary high voltage side bushings and the second sensor is coupled to each of the three respective secondary low voltage side bushings. In some embodiments in the case of a single three-phase transformer, the first sensor is coupled to each of the three respective primary high voltage side bushings and the second sensor is coupled to each of the three respective secondary low voltage side bushings.

In some embodiments, the first sensor further comprises a buried current transformer

coupled between a test tap and the one or more processors.

In some embodiments in the case of a single phase transformer, the first sensor is coupled to each of the three respective primary high voltage side bushings and the second sensor is coupled to each of the three respective secondary low voltage side bushings and the processor can be configured to compare pairings of the first sensor and the second sensors from respective primary high voltage side bushings and secondary low voltage side bushings and generate an alert when detecting a deviation over a predetermined threshold between sampled readings for the sampled data over time among the respective pairings.

In some embodiments, a system for on-line monitoring a condition of a transformer having three high voltage side bushings and corresponding three low voltage side bushings can include one or more processors having as inputs: a test tap from a first high voltage side bushing and a test tap from a first low voltage side bushing; a test tap from a second high voltage side bushing and a test tap from a second low voltage side bushing; and a test tap from a third high voltage side bushing and a test tap from a third low voltage side bushing. The one or more processors can be configured to perform the operations of simultaneously sampling data on a same phase for first corresponding high and low voltage side bushings, second high and low voltage side bushings, and third high and low voltage side bushings, comparing the sampled data over time to provide sampled readings on the same phase, and generating an alert upon detection of a deviation over a predetermined threshold between sampled readings for the sampled data over time.

In some embodiments, the one or more processors are further configured to compare a phase angle of leakage between the respective high voltage side bushing and the low voltage side bushing. In some embodiments, the one or more processors are configured to compare and track a high to low angle power factor variation over time, and wherein a variation above a threshold among pairings of readings among the respective high and low side voltage bushings is indicative of a fault with a bushing having the variation above the threshold.

In some embodiments, the one or more processors further have as inputs a first buried current transformer coupled to the test tap from the first high voltage side bushing, a second buried current transformer coupled to the test tap from the second high voltage side bushing, and a third buried current transformer coupled to the test tap from the third high voltage side bushing. In some embodiments, the first, second, and third buried current transformers compensate for varying loads to the transformer and/or can be used measure current at different loads and to extrapolate a dependence of phase angle to exclude the influence of the phase angle on bushing power factor readings.

In some embodiments, a method of on-line transformer bushings power factor monitoring for a power transformer having three high voltage side bushings and corresponding three low voltage side bushings can include using one or more processors configured to obtain data samples from comparisons between test taps from a first high voltage side bushing and a corresponding first low voltage side bushing, obtain data samples from comparisons between test taps from a second high voltage side bushing and a corresponding second low voltage side bushing, and obtain data samples from comparisons between test tap from a third high voltage side bushing and a third low voltage side bushing. The one or more processors can further obtain the data samples simultaneously from at least one pair of corresponding high and low side voltage bushings, compare the sampled data for corresponding high and low side voltage bushings over time to provide sampled readings on the same phase, and generate an alert upon detection of a deviation over a predetermined threshold between sampled readings for the sampled data over time.

In some embodiments, the method can compare a phase angle of leakage between the respective high voltage side bushing and the low voltage side bushing. In some embodiments, the method compares and tracks a high to low angle power factor variation over time, where a variation above a threshold among pairings of readings among the respective high and low side voltage bushings is indicative of a fault with a bushing having the variation above the threshold.

In some embodiments, the one or more processors further have as inputs a first buried current transformer coupled to the test tap from the first high voltage side bushing, a second buried current transformer coupled to the test tap from the second high voltage side bushing, and a third buried current transformer coupled to the test tap from the third high voltage side bushing and where the buried current transformers are used to compensate for varying load when calculating power factor measurements.

### BRIEF DESCRIPTION OF DRAWINGS

FIG. 1 is a block diagram of a monitoring system in accordance with an embodiment;

FIG. 2 is a vector representation of the signal for monitoring transformer bushing dielectric loses such as Dissipation Factor and Power Factor in accordance with an embodiment;

FIG. 3 is vector representation comparing signals from primary and secondary transformer sides for measuring or monitoring transformer bushing dielectric losses in accordance with an embodiment;

FIG. 4 is a chart representing a high to low angle power factor variation over time for three high and low voltage bushing pairings where one of the pairings indicates degradation in accordance with an embodiment;

FIG. 5 is a chart representing a high to low angle power factor variation over time for three high and low voltage bushing pairings where all pairings appear in good operating condition in accordance with an embodiment;

FIG. 6 is another block diagram of a monitoring system in accordance with an embodiment;

FIG. 7 is a flow chart illustrating a method of on-line transformer bushings power factor monitoring in accordance with the embodiments;

And FIG. 8 is a block diagram of a system in accordance with the embodiments.

### DETAILED DESCRIPTION

In accordance with one or more embodiments, a system 10 is designed for monitoring the technical state of a power transformer 12 using various methods that do not necessarily include the all the detriments yet include many of their benefits with respect to various existing techniques as described in the background above including the phase-to-phase bushing power factor (adjacent phase) technique, the external reference with a voltage transformer or coupling capacitor voltage transformer technique, or the comparison technique.

In some embodiments, the system 10 can include a first sensor 15a coupled to a primary high voltage side bushing 14a for monitoring power transformer bushing dielectric losses on a primary high voltage side of the transformer, a second sensor 17a coupled to a secondary low voltage side bushing 16a for monitoring power transformer bushing dielectric losses on a secondary low voltage side of the transformer, and one or more processors 18 coupled to the first sensor 15a and the second sensor 17a. The one or more processors 18 are configured to perform the operations of simultaneously sampling data from the first sensor 15a and the second sensor 17a, where the primary high voltage side bushing 14a and the secondary low voltage side bushing 16a are operating on a same phase, comparing the sampled data over time to provide sampled readings on the same phase, and generating an alert upon detection of a deviation over a predetermined threshold between sampled readings for the sampled data over time.

In some embodiments, the first sensor 15a is a test tap coupled to the primary high voltage side bushing 14a and the second sensor 17a is a test tap coupled to the secondary low voltage side bushing 16a. In some embodiments, the first sensor 15a and second sensor 17a compare a phase angle of leakage between the primary high voltage side bushing 14a and the secondary low voltage side bushing 16a. In some embodiments, the transformer is a single phase transformer and in others it is a single three-phase transformer having three primary high voltage side bushings and three secondary low voltage side bushings. In some embodiments, the transformer is a three single-phase transformer having three primary high voltage side bushings and three secondary low voltage side bushings.

In some embodiments, the first sensor (15a, 15b, and 15c) is coupled to each of the three respective primary high voltage side bushings (14a, 14b, and 14c) and the second sensor (17a, 17b, and 17c) is coupled to each of the three respective secondary low voltage side bushings (16a, 16b, and 16c) for a three single-phase transformer. In some embodiments in the case of a single three-phase transformer, the first sensor (15a, 15b, and 15c) is coupled to each of the three respective primary high voltage side bushings (14a, 14b, and 14c) and the second sensor (17a, 17b, and 17c) is coupled to each of the three respective secondary low voltage side bushings (16a, 16b, and 16c).

Dissipation factor (DF) analysis is used to assess bushings and insulation condition. The bushing insulation is a dielectric material, which can be considered in an ideal case as a pure capacitor. Over time, the permittivity of the material changes due to aging, and it causes capacitive current variations. Additionally, resistive leakage current increases due to the deterioration of the material.

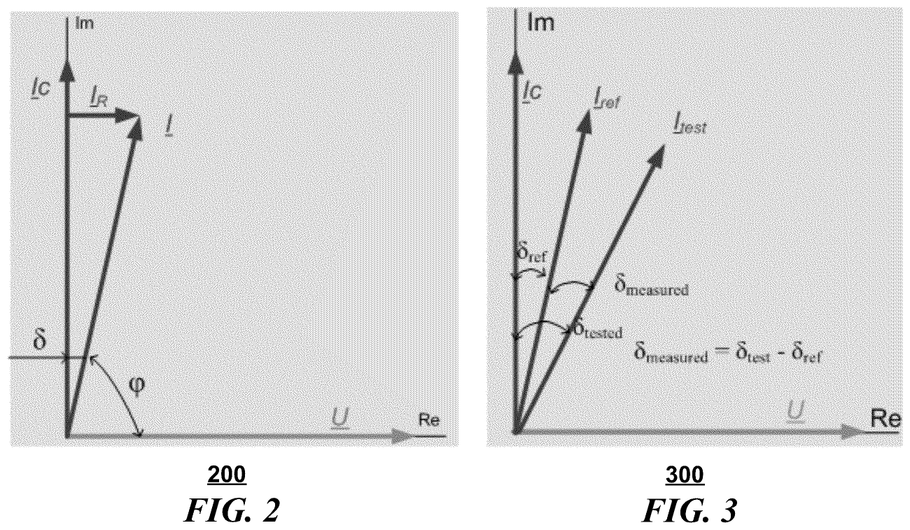

Dissipation factor, also known as power factor or tan delta, presents the ratio between the capacitance current and resistive current components through the insulation. Ideal insulation shows the capacitive current leading the applied voltage by 90 degrees as shown in the chart 200 of FIG. 2. Hence, the total current I equals the capacitive current I_{C}, and the DF (tan δ) is zero.

However, some leakage current (resistive current I_{R}) through the insulation surface increases due to the contamination or carbonization in the insulation, and it represents the resistive loss. The term tan delta (tan δ) presents the ratio between the resistive I_{R} and capacitive I_{C} current components, and power factor (cos θ) represents the fraction of I_{R} with respect to the total current I.

FIG. 3 is a vector representation 300 comparing signals from primary and secondary transformer sides for measuring or monitoring transformer bushing dielectric losses in accordance with an embodiment

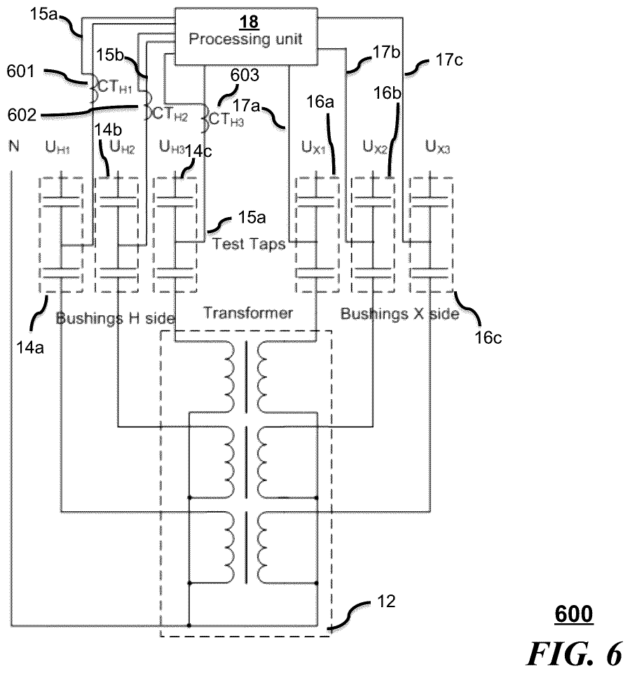

In some embodiments with reference to a system 600 of FIG. 6, the first sensor further includes a buried current transformer 601 coupled between a test tap 15a and the one or more processors 18. In other words, a first sensor can include a combination of an input from a first test tap 15a and an input from the buried current transformer 601 for a single phase transformer having just a primary high voltage side bushing 14a and an input from a first test tap 17a from a secondary low voltage side bushing 16a. Although reference is made to system 6 which has multiple high and low voltage side bushings, the same principles would apply to a single phase transformer having a single primary high voltage side bushing and single secondary low voltage side bushing.

For a single three-phase transformer or three single-phase transformer and with further reference to FIG. 6, the “first sensor” would include a corresponding combination of inputs from first test taps (15a, 15b, 15c) and inputs from the buried current transformers (601, 602, and 603) from the corresponding primary high voltage side bushings (14a, 14b, and 14c) and the “second sensor” would include inputs from the test taps (17a, 17b, and 17c) for the corresponding secondary low voltage side bushings (16a, 16b, and 16c).

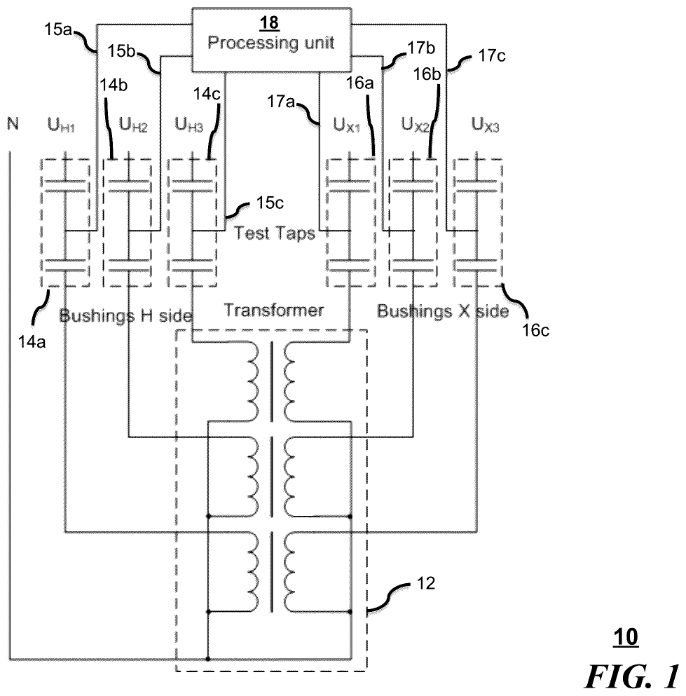

The system measures the dielectric losses utilizing the method from FIG. 1 (Adjacent phase). But in addition, it watches for the changes and correlation of the measured signals in reference to the respective one phase Primary to Secondary bushings (High-to-Low). Simultaneous measurement is required for at least two bushings of one phase.

If all bushings of the transformer are in good condition, the High-to-Low values for three phases corresponds to each other with small variation and trends laying very close to each other as shown in the chart 500 of FIG. 5. In this case the system can detect the separation of one of the phases, but the alarm threshold cannot be set due to dynamically changing of the High-to-Low values.

If the system utilizes the CT sensors (601, 602, and 603) for the measurement of the transformer load, the variation of the High-to-Low values could be compensated by the load coefficient. This addition to the method allows for the set up of constant alarm thresholds for the High-to-Low values.

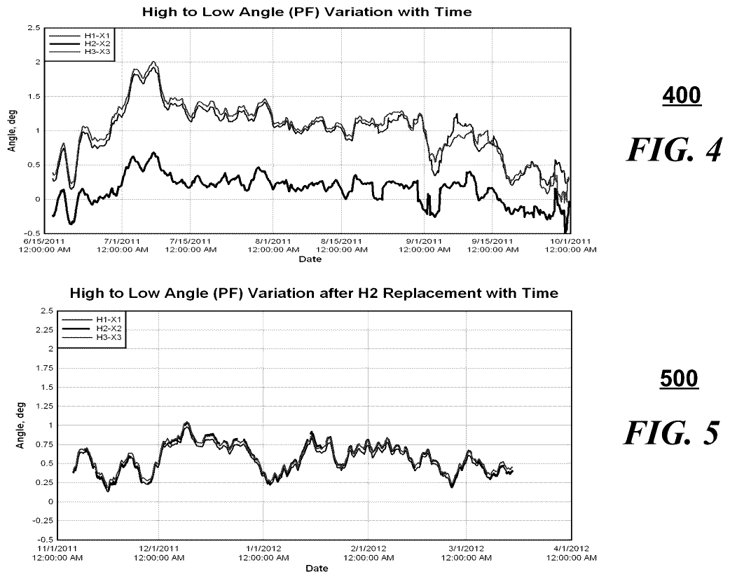

In some embodiments in the case of a single phase transformer having three primary high side bushings and three secondary low side bushings, the first sensor (15a, 15b, and 15c) is coupled to each of the three respective primary high voltage side bushings (14a, 14b, and 14c) and the second sensor (17a, 17b, and 17c) is coupled to each of the three respective secondary low voltage side bushings (16a, 16b, and 16c) and the processor 18 can be configured to compare pairings (15a & 17a, 15b & 17b, and 15c & 17c) of the first sensor and the second sensors from respective primary high voltage side bushings and secondary low voltage side bushings and generate an alert when detecting a deviation over a predetermined threshold between sampled readings for the sampled data over time among the respective pairings. Such a predetermined threshold can be made programmatically and set to be as sensitive as desired. For example, with reference to the chart 400 of FIG. 4, a deviation of over 0.25 degrees on average over time or possibly as little as 0.1 degrees over time (between high and low angle PF variation) may be enough to set an alarm. As shown in the chart 500 of FIG. 5, minor deviations among pairings indicates all bushings appear to be in good working order.

In some embodiments, a system 10 for on-line monitoring a condition of a transformer 12 having three high voltage side bushings (14a, 14b, and 14c) and corresponding three low voltage side bushings (16a, 16b, and 16c) can include one or more processors 18 having as inputs: a test tap 15a from a first high voltage side bushing 14a and a test tap 17a from a first low voltage side bushing 16a; a test tap 15b from a second high voltage side bushing 14b and a test tap 17b from a second low voltage side bushing 16b; and a test tap 15c from a third high voltage side bushing 14c and a test tap 17c from a third low voltage side bushing 16c. The one or more processors 18 can be configured to perform the operations of simultaneously sampling data on a same phase for first corresponding high and low voltage side bushings (14a & 16a), second high and low voltage side bushings (14b & 16b), and third high and low voltage side bushings (14c & 16b), comparing the sampled data over time to provide sampled readings on the same phase, and generating an alert upon detection of a deviation over a predetermined threshold between sampled readings for the sampled data over time.

In some embodiments, the one or more processors 18 are further configured to compare a phase angle of leakage between the respective high voltage side bushing and the low voltage side bushing. In some embodiments, the one or more processors 18 are configured to compare and track a high to low angle power factor variation over time, and where a variation above a threshold among pairings of readings among the respective high and low side voltage bushings is indicative of a fault with a bushing or a given corresponding pair of (high and low) bushings having the variation above the threshold. Some existing techniques will fail to find faults or degradation when a bushing pairing both degrade in a similar fashion concurrently, but the embodiments (using the high to low or low to high comparison) techniques herein provide a way to detect such degradation among bushing pairings.

In some embodiments, the one or more processors 18 further have as inputs a first buried current transformer 601 coupled to the test tap 15a from the first high voltage side bushing 14a, a second buried current transformer 602 coupled to the test tap 15b from the second high voltage side bushing 14b, and a third buried current transformer 603 coupled to the test tap 15c from the third high voltage side bushing 14c. In some embodiments, the first, second, and third buried current transformers (601, 602, and 603) compensate for varying loads to the transformer 600 and/or can be used measure current at different loads and to extrapolate a dependence of phase angle to exclude the influence of the phase angle on bushing power factor readings.

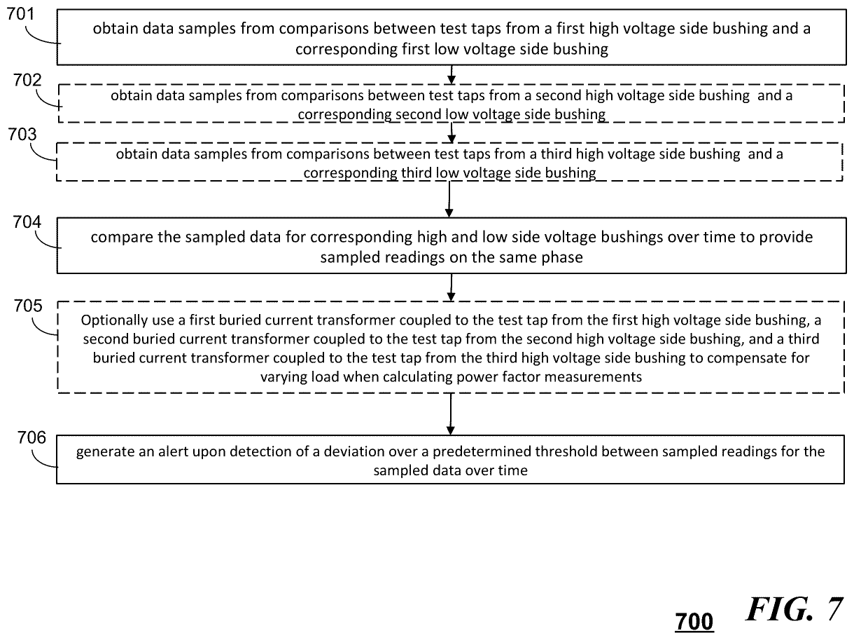

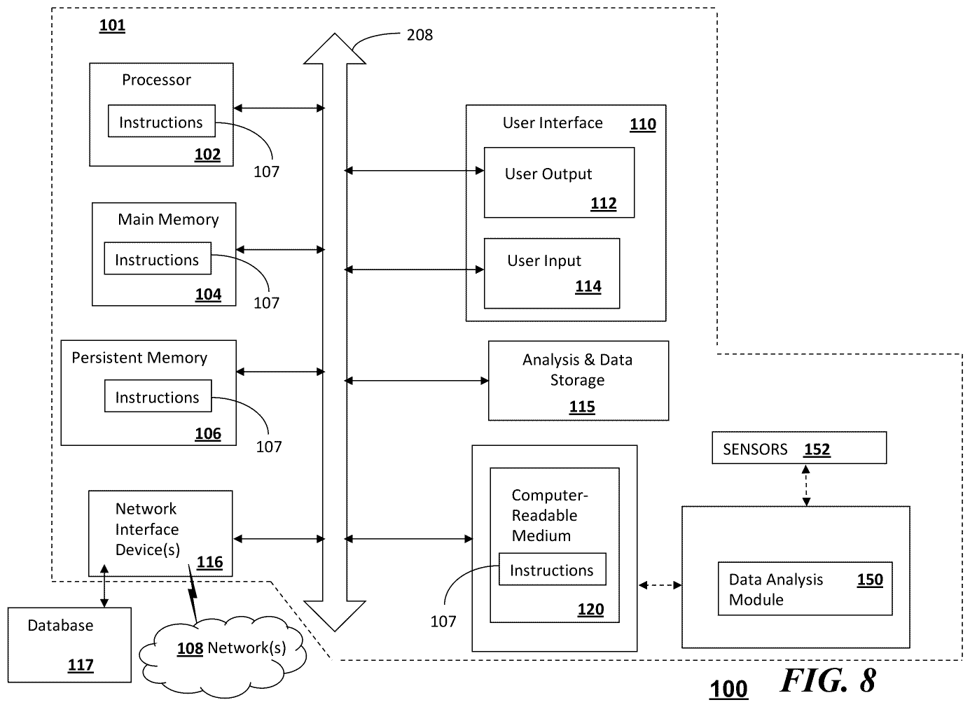

In some embodiments and with further reference to FIG. 7, a method 700 of on-line transformer bushings power factor monitoring for a power transformer (10 or 600) having at least one high voltage side bushing and at least one corresponding high voltage side bushing or in other cases three high voltage side bushings and corresponding three low voltage side bushings can include using one or more processors (18) configured at 701 to obtain data samples from comparisons between test taps from at least a first high voltage side bushing and at least a corresponding first low voltage side bushing, (in the case where three high and low bushings exist) obtain at 702 data samples from comparisons between test taps from a second high voltage side bushing and a corresponding second low voltage side bushing, and (and again in the case where three high and low bushings exist) at 703 obtain data samples from comparisons between test tap from a third high voltage side bushing and a third low voltage side bushing. The one or more processors can further obtain the data samples simultaneously from at least one pair of corresponding high and low side voltage bushings, compare the sampled data for corresponding high and low side voltage bushings over time at 704 to provide sampled readings on the same phase, and generate an alert at 706 upon detection of a deviation over a predetermined threshold between sampled readings for the sampled data over time.

In some embodiments, the method can compare a phase angle of leakage current between the respective high voltage side bushing and the low voltage side bushing. In some embodiments, the method compares and tracks a high to low angle power factor variation over time, where a variation above a threshold among pairings of readings among the respective high and low side voltage bushings is indicative of a fault with a bushing having the variation above the threshold.

In some embodiments and with further reference to step 705 in FIG. 7, the one or more processors further have as inputs a first buried current transformer coupled to the test tap from the first high voltage side bushing, a second buried current transformer coupled to the test tap from the second high voltage side bushing, and a third buried current transformer coupled to the test tap from the third high voltage side bushing and where the buried current transformers are used to compensate at 905 for varying load when calculating power factor measurements.

Various embodiments of the present disclosure can be implemented on an information processing system. The information processing system is capable of implementing and/or performing any of the functionality set forth above. Any suitably configured processing system can be used as the information processing system in embodiments of the present disclosure. The information processing system is operational with numerous other general purpose or special purpose computing system environments, networks, or configurations. Examples of well-known computing systems, environments, and/or configurations that may be suitable for use with the information processing system include, but are not limited to, personal computer systems, server computer systems, thin clients, hand-held or laptop devices, multiprocessor systems, mobile devices, microprocessor-based systems, set top boxes, programmable consumer electronics, network PCs, minicomputer systems, mainframe computer systems, Internet-enabled television, and distributed cloud computing environments that include any of the above systems or devices, and the like.

For example, a user with a mobile device may be in communication with a server configured to implement the high voltage to low voltage bushing comparison (or alternatively low voltage bushing to high voltage bushing comparison) technique herein, according to an embodiment of the present disclosure. The mobile device can be, for example, a multi-modal wireless communication device, such as a “smart” phone, configured to store and execute mobile device applications (“apps”). Such a wireless communication device communicates with a wireless voice or data network using suitable wireless communications protocols. The user signs in and accesses the one or more service layers, including the various modules described herein. The service layer can in turn communicate with various databases, such as a database that may contain past readings for various transformers and their corresponding high/low voltage bushing comparisons. A generic content repository may, for example, may contain other data to provide location information, servicing or other pertinent information for the respective transformers on a given power grid or network. The service layer queries these databases and presents responses back to the user based upon the rules and interactions of existing interfacing modules that can exist.

The monitoring system may include, inter alia, various hardware components such as processing circuitry executing modules that may be described in the general context of computer system-executable instructions, such as program modules, being executed by the system. Generally, program modules can include routines, programs, objects, components, logic, data structures, and so on that perform particular tasks or implement particular abstract data types. The modules may be practiced in various computing environments such as conventional and distributed cloud computing environments where tasks are performed by remote processing devices that are linked through a communications network. In a distributed cloud computing environment, program modules may be located in both local and remote computer system storage media including memory storage devices. Program modules generally carry out the functions and/or methodologies of embodiments of the present disclosure, as described above.

In some embodiments, a system includes at least one memory and at least one processor of a computer system communicatively coupled to the at least one memory. The at least one processor can be configured to perform a method including methods described above including the high to low or low to high voltage bushing comparisons.

According yet to another embodiment of the present disclosure, a computer readable storage medium comprises computer instructions which, responsive to being executed by one or more processors, cause the one or more processors to perform operations as described in the methods or systems above or elsewhere as described herein.

As shown in FIG. 8, an information processing system 101 of a system 100 can be communicatively coupled with a data analysis module 150 and a group of client or other devices, or coupled to a presentation device for display (such as user output 112) at any location at a terminal or server location. According to this example, at least one processor 102, responsive to executing instructions 107, performs operations to communicate with the data analysis module 150 via a bus architecture 208, as shown. The at least one processor 102 is communicatively coupled with main memory 104, persistent memory 106, and a computer readable medium 120. The processor 102 is communicatively coupled with an Analysis & Data Storage 115 that, according to various implementations, can maintain stored information used by, for example, the data analysis module 150 and more generally used by the information processing system 100. Optionally, this stored information can be received from the client or other devices. For example, this stored information can be received periodically from the client devices and updated or processed over time in the Analysis & Data Storage 115. Additionally, according to another example, a history log can be maintained or stored in the Analysis & Data Storage 115 of the information processed over time. The data analysis module 150, and the information processing system 100, can use the information from the history log such as in the analysis process and in making decisions related to determining whether data measured is considered an outlier or not. In other words, the data analysis module 150, for example, can contain algorithms in accordance with the embodiments that determine if the high/low or low/high voltage bushing comparison readings for a given high/low bushing pairing is degrading beyond a predetermined threshold or even if a particular bushing within a pairing is degrading beyond the predetermined threshold. Data tables or algorithms that may also take into account and compensate for load, temperature or other factors that vary over time may also be included.

The computer readable medium 120, according to the present example, can be communicatively coupled with a reader/writer device (not shown) that is communicatively coupled via the bus architecture 208 with the at least one processor 102. The instructions 107, which can include instructions, configuration parameters, and data, may be stored in the computer readable medium 120, the main memory 104, the persistent memory 106, and in the processor's internal memory such as cache memory and registers, as shown.

The information processing system 100 includes a user interface 110 that comprises a user output interface 112 and user input interface 114. Examples of elements of the user output interface 112 can include a display, a speaker, one or more indicator lights, one or more transducers that generate audible indicators, and a haptic signal generator. Examples of elements of the user input interface 114 can include a keyboard, a keypad, a mouse, a track pad, a touch pad, a microphone that receives audio signals, a camera, a video camera, or a scanner that scans images. The received signals, for example, can be converted to electronic digital representation and stored in memory, and optionally can be used with corresponding software executed by the processor 102 to receive user input data and commands, or to receive test data for example.

A network interface device 116 is communicatively coupled with the at least one processor 102 and provides a communication interface for the information processing system 100 to communicate via one or more networks 108. The networks 108 can include wired and wireless networks, and can be any of local area networks, wide area networks, or a combination of such networks including (but not limited to) networks commonly used for telemetry such as SCADA. For example, wide area networks including the interne and the web can inter-communicate the information processing system 100 with other one or more information processing systems that may be locally, or remotely, located relative to the information processing system 100. It should be noted that mobile communications devices, such as mobile phones, Smart phones, tablet computers, lap top computers, and the like, which are capable of at least one of wired and/or wireless communication, are also examples of information processing systems within the scope of the present disclosure. The network interface device 116 can provide a communication interface for the information processing system 100 to access the at least one database 117 according to various embodiments of the disclosure.

The instructions 107, according to the present example, can include instructions for monitoring, instructions for analyzing, instructions for retrieving and sending information and related configuration parameters and data. It should be noted that any portion of the instructions 107 can be stored in a centralized information processing system or can be stored in a distributed information processing system, i.e., with portions of the system distributed and communicatively coupled together over one or more communication links or networks.

FIG. 7 illustrates an example of methods or process flows, according to various embodiments of the present disclosure, which can operate in conjunction with the information processing system 100 of FIG. 8.

1. A system for on-line monitoring a condition of a transformer, comprising:
a first sensor coupled to a primary high voltage side of the transformer for online monitoring power transformer bushing dielectric losses on a primary high voltage side of the transformer;
a second sensor coupled to a secondary low voltage side for online monitoring power transformer bushing dielectric losses on a secondary low voltage side of the transformer; and
one or more processors coupled to the first sensor and the second sensor;
a first buried current transformer only from a first high voltage side, a second buried current transformer only from a second high voltage side, and a third buried current transformer only from a third high voltage side of the transformer providing inputs to the one or more processors and wherein the first, second, and third buried current transformers compensate for varying loads on the transformer;
one or more processors coupled to the first sensor and the second sensor, wherein the one or more processors are configured to perform the operations of:
simultaneously sample data from the first sensor and the second sensor, wherein the primary high voltage side and the secondary low voltage side are operating on a same phase;
compare the simultaneously sampled data over time to provide sampled readings on the same phase between the primary high voltage side and the secondary low voltage side; and
generate an alert upon detection of a deviation over a predetermined threshold between the simultaneously sampled readings for the simultaneously sampled data over time.

2. The system of claim 1, wherein the first sensor includes a test tap coupled to a primary high voltage side bushing and the second sensor includes a test tap coupled to a secondary low voltage side bushing.

3. The system of claim 1, wherein the first sensor and second sensor further use respective buried current transformers to compare a phase angle of leakage between the primary high voltage side and the secondary low voltage side and are used to measure current at different loads and to extrapolate a dependence of the phase angle to exclude the influence of the phase angle on bushing power factor readings during online monitoring.

4. The system of claim 1, wherein the transformer is a single phase transformer.

5. The system of claim 1, wherein the transformer is a single three-phase transformer having three primary high voltage side bushings and three secondary low voltage side bushings.

6. The system of claim 5, wherein the first sensor is coupled to each of the three respective primary high voltage side bushings and the second sensor is coupled to each of the three respective secondary low voltage side bushings.

7. The system of claim 1, wherein the transformer is a three single-phase transformer having three primary high voltage side bushings and three secondary low voltage side bushings.

8. The system of claim 7, wherein the first sensor is coupled to each of the three respective primary high voltage side bushings and the second sensor is coupled to each of the three respective secondary low voltage side bushings.

9. The system of claim 1, wherein the first sensor further comprises a buried current transformer providing an input to the one or more processors.

10. The system of claim 5, wherein the first sensor is coupled to each of the three respective primary high voltage side bushings and the second sensor is coupled to each of the three respective secondary low voltage side bushings and wherein the processor is configured to compare pairings of the first sensor and the second sensors from respective primary high voltage side bushings and secondary low voltage side bushings and generate an alert when detecting a deviation over a predetermined threshold between sampled readings for the sampled data over time among the respective pairings without use of external injection signals.

11. A system for on-line monitoring a condition of a transformer having three high voltage side bushings and corresponding three low voltage side bushings, comprising:
one or more processors having as inputs:
a first sensor from a first high voltage side and a second sensor from a first low voltage side;
a third sensor from a second high voltage side and a fourth sensor from a second low voltage side;
a fifth sensor from a third high voltage side and a sixth sensor from a third low voltage side;
a first buried current transformer only from the first high voltage side, a second buried current transformer only from the second high voltage side, and a third buried current transformer only from the third high voltage side of the transformer;
wherein the one or more processors are configured to perform the operations of:
simultaneously sample data on same phase for first corresponding high and low voltage side bushings, second high and low voltage side bushings, and third high and low voltage side bushings;
compare the simultaneously sampled data over time to provide sampled readings on the same phase between the respective primary high voltage side and the respective secondary low voltage side for online monitoring the condition of the transformer wherein at least the sensors on the high voltage sides compensate for varying loads to the transformer during the online monitoring;
generate an alert upon detection of a deviation over a predetermined threshold between simultaneously sampled readings for the simultaneously sampled data over time.

12. The system of claim 11, wherein the one or more processors are further configured to use the first, the second, and the third buried current transformers to compare a phase angle of leakage between the respective high voltage side and the low voltage side of the transformer and are used to measure current at different loads and to extrapolate a dependence of the phase angle to exclude the influence of the phase angle on bushing power factor readings.

13. The system of claim 11, wherein the one or more processors are configured to compare and track a high to low angle power factor variation over time during online monitoring of the transformer, and wherein a variation above a threshold among pairings of readings among the respective high and low side voltage bushings is indicative of a fault with a bushing having the variation above the threshold.

14. The system of claim 11, wherein the one or more processors further have as inputs a first buried current transformer coupled to the first high voltage side, a second buried current transformer coupled to the second high voltage side, and a third buried current transformer coupled to the third high voltage side of the transformer.

15. The system of claim 14, wherein the first, second, and third buried current transformers compensate for varying loads to the transformer during online monitoring of the transformer.

16. The system of claim 14, wherein the buried current transformers are used to measure current at different loads and to extrapolate a dependence of phase angle to exclude the influence of the phase angle on bushing power factor readings during online monitoring of the transformer.

17. A method of on-line transformer bushings power factor monitoring for a power transformer having three high voltage side bushings and corresponding three low voltage side bushings, comprising:
using one or more processors configured to:
simultaneously obtain data samples from comparisons between buried current transformers from a first high voltage side and a corresponding first low voltage side of the power transformer;
simultaneously obtain data samples from comparisons between buried current transformers from a second high voltage side and a corresponding second low voltage side of the power transformer;
simultaneously obtain data samples from comparisons between buried current transformers from a third high voltage side and a third low voltage side of the power transformer;
wherein the buried current transformers compensate for varying loads to the transformer, measure current at different loads, and extrapolate a dependence of phase angle to exclude the influence of the phase angle on bushing power factor readings during online monitoring of the transformer;
compare the simultaneously sampled data for corresponding high and low side voltage bushings over time to provide sampled readings on the same phase between the corresponding primary high voltage side and the secondary low voltage side;
generate an alert upon detection of a deviation over a predetermined threshold between the simultaneously sampled readings for the simultaneously sampled data over time; and wherein the one or more processors further have as inputs a first buried current transformer only from a first high voltage side, a second buried current transformer only from a second high voltage side, and a third buried current transformer only from a third high voltage side of the transformer.

18. The method of claim 17, wherein the one or more processors are further configured to compare a phase angle of leakage between the respective high voltage side bushing.

19. The method of claim 17, wherein the one or more processors are configured to compare and track during online monitoring of the transformer a high to low angle power factor variation over time, and wherein a variation above a threshold among pairings of readings among the respective high and low voltage side bushings is indicative of a fault with a bushing having the variation above the threshold.

20. The method of claim 17, wherein the one or more processors further have as inputs a first buried current transformer from a first high voltage side, a second buried current transformer from a second high voltage side, and a third buried current transformer from a third high voltage side of the transformer.
